(19) United States
(12) Patent Application Publication
(10) Pub. No.: US 2015/0162346 A1
(43) Pub. Date: Jun. 11, 2015

(54) Semiconductor Package

(71) Applicant: Dongbu Hitek Co., Ltd., Seoul (KR)

(72) Inventors: Kee Joon Choi, Gyeonggi-do (KR); Bum Seok Kim, Seoul (KR); Moon Young Lee, Incheon (KR); Sun Young Lee, Gyeonggi-do (KR)

(21) Appl. No.: 14/300,899

(22) Filed: Jun. 10, 2014

(30) Foreign Application Priority Data
Dec. 11, 2013 (KR) 10-2013-0153968

(51) Int. Cl. H01L 27/12; H01L 23/367; H01L 23/00

(52) U.S. Cl. CPC H01L 27/124; H01L 24/14; H01L 23/367; H01L 2224/14519; H01L 2924/1304; H01L 2924/1426; H01L 2224/13026; H01L 2224/13022

(57) ABSTRACT

Disclosed is a semiconductor package. The semiconductor package includes a substrate formed with transistors, power metal lines formed on the substrate, data metal lines formed on the substrate to transmit and receive data to and from the transistors, and an insulating layer formed on the substrate, the power metal lines, and the data metal lines. Herein, the insulating layer has openings partially exposing the power metal lines.

### CROSS-REFERENCE TO RELATED APPLICATION

This application claims priority to Korean Patent Application No. 10-2013-0153968 filed on Dec. 11, 2013 and all the benefits accruing therefrom under 35 U.S.C. §119, the contents of which are incorporated by reference in their entirety.

### BACKGROUND

The present disclosure relates to a semiconductor package, and more particularly, to a semiconductor package having a structure capable of effectively releasing heat generated from the semiconductor package.

General liquid crystal displays (LCDs) display images by controlling optical transmittance of liquid crystal using an electric field. In order to display images, LCDs include a liquid crystal panel arranged with liquid crystal cells as a matrix and a driving circuit for driving the liquid crystal panel. Since such LCDs are capable of being more easily miniaturized than cathode ray tubes, these devices are generally used as display units for potable televisions or laptop personal computers.

In order to drive a liquid panel of an LCD, a data driver and a gate driver are necessary. The data driver and the gate driver are integrated with a plurality of integrated circuits (ICs). Each of integrated data driving ICs and gate driving ICs is either mounted on a tape carrier package (TCP) and connected to a liquid crystal using a tape automated bonding (TAB) method or mounted on a liquid crystal panel using a chip on glass (COG) method.

As technology has advanced, LCDs have increased in display resolution and ICs are increasingly integrated into the design of these LCDs. However, these technological advances have resulted in an increased need for improved cooling measures. As more and more electronic components are confined to smaller and smaller spaces, heat build up may impact the stability of circuits in the device and damage a flexible base film of the display. In the case of ultra high resolution display devices, such as those employed in high definition or ultra high definition televisions, it is necessary to consider the heat resistance of a frame forming an external shape of a television.

Development of improved heat release technologies for ICs of a display may result in a decreased need for heat tolerance of other components of the LCD device. As such, improved heat release measures may allow for additional design and/or engineering solutions to overcome limitations in design or material of various display devices used with the ICs.

FIGS. 1 and 2 illustrate a configuration of a semiconductor package functioning as a driver IC used for a display device or another computer device. FIG. 1 is a cross-sectional view of a general semiconductor package, and FIG. 2 illustrates a generally used heat release configuration of the semiconductor package of FIG. 1.

Referring to FIG. 1, the semiconductor package includes a transistor 10 transmitting a signal, at least one insulating layer formed on the transistor 10, metal patterns 21, 22, 23, and 40 formed on the insulating layer, and via contacts 30 allowing the metal patterns 21, 22, 23, 23, and 40 to be electrically connected to one another. The semiconductor package further includes insulating layers 51 and 52 formed on the upper metal pattern 40 to be used as protection layers for protecting a device. When a semiconductor package having this structure is used as a driver IC of a display device, a large amount of heat is generated from the application of power to electrode lines arranged as a matrix or to transmit signals to display an image on the display device. This heat buildup is transferred along the metal patterns and via contacts (refer to FIG. 1 for an arrow). However, insulating layers on top of the device reduce the efficiency of this heat transfer.

An example general semiconductor package, such as a driver IC, is shown in FIG. 2. This semiconductor package further includes heat sinks 2 and 3 having a dummy chip shape on both sides of the semiconductor package 1. That is, the heat sinks 2 and 3 formed of metallic materials for heat release are provided on the both sides of the semiconductor package 1. This structure facilitates the release of a large amount of heat from the semiconductor package 1. However, the structure, in which heat sinks are provided on the both sides of the semiconductor package 1, has limitations. This structure results in an increase in the size of the display device, as it must be structured to incorporate the semiconductor package. Also, newer commercial display devices attempt to minimize the size and profile of the frame and display bezel in order to present a slimmer profile. These newer designs provide less area within which to accommodate heat sinks and other devices for improving the heat release efficiency of an IC. Furthermore, damage caused by heat generated by the driver IC may occur in an LCD panel, generating interference or otherwise preventing the LCD from operating.

### SUMMARY

The present disclosure provides a structure for heat release formed on a semiconductor package without the need to provide an additional heat release structure on sides of the semiconductor package to release heat of the semiconductor package.

The present disclosure also provides a heat release structure capable of naturally releasing heat generated by a semiconductor package together with transfer of the heat and capable of significantly reducing an area occupied by a driver integrated circuit (IC).

In accordance with an exemplary embodiment, a semiconductor package may include a substrate formed with transistors, power metal lines formed on the substrate, data metal lines formed on the substrate to transmit and receive data to and from the transistors, and an insulating layer formed on the substrate, the power metal lines, and the data metal lines. Herein, the insulating layer may have openings partially exposing the power metal lines.

The semiconductor package may further include metal contacts formed in the openings and a heat release layer formed on the metal contacts and the insulating layer and connected to the power metal lines through the metal contacts.

The heat release layer may be formed of metal material and may include a plurality of heat release patterns formed on the insulating layer.

The heat release layer may include a first area located over the power metal lines and a second area located over the data metal lines.

The first area and the second area may be electrically connected to each other.

The semiconductor package may further include a passivation layer formed on the heat release layer.

The heat release layer may have a plurality of heat release holes partially exposing the insulating layer.

The heat release holes may have a diameter gradually reducing from a top surface to a bottom surface of the heat release layer.

The substrate may include a pad region for external connection. In this case, connection lines and pad bumps connected to the connection lines may be formed in the pad region, and the power metal lines and the connection lines may be formed of the same material.

The heat release bumps connected to the power metal lines may be formed in the openings, respectively.

The heat release bumps may be formed to protrude from the insulating layer.

The heat release bumps and the pad bumps may be formed of the same material.

In accordance with another exemplary embodiment, a semiconductor package for controlling a display panel may include a substrate formed with transistors, power metal lines formed on the substrate, data metal lines formed on the substrate to transmit and receive data to and from the transistors, an insulating layer formed on the substrate, the power metal lines, and the data metal lines, a heat release layer formed on the insulating layer, and a plurality of metal contacts connecting the power metal lines with the heat release layer to each other through the insulating layer.

The heat release layer may include a first area located over the power metal lines and a second area located over the data metal lines.

In accordance with still another exemplary embodiment, a semiconductor package may include a substrate formed with transistors, power metal lines formed on the substrate, data metal lines formed on the substrate to transmit and receive data to and from the transistors, and an insulating layer formed on the substrate, the power metal lines, and the data metal lines. Herein, the insulating layer may have heat release holes partially exposing the power metal lines.

The semiconductor package may further include heat release bumps formed on the power metal lines exposed by the heat release holes.

The above summary is provided merely for purposes of summarizing some example embodiments to provide a basic understanding of some aspects of the invention. Accordingly, it will be appreciated that the above-described embodiments are merely examples and should not be construed to narrow the scope or spirit of the invention in any way. It will be appreciated that the scope of the invention encompasses many potential embodiments in addition to those here summarized, some of which will be further described below.

### BRIEF DESCRIPTION OF THE DRAWINGS

Exemplary embodiments can be understood in more detail from the following description taken in conjunction with the accompanying drawings which are not necessarily drawn to scale, in which:

FIG. 1 is a cross-sectional view of a general semiconductor package;

FIG. 2 illustrates a generally used heat release configuration of the semiconductor package of FIG. 1;

FIG. 3 is a view of a top surface of a semiconductor package according to an exemplary embodiment;

FIG. 4 is a cross-sectional view of the semiconductor package of FIG. 3;

FIGS. 5 to 7 are cross-sectional views illustrating a method of manufacturing the semiconductor package shown in FIG. 4;

FIGS. 8 and 9 are perspective views of a top and a bottom of a heat release layer shown in FIG. 7;

FIG. 10 is a top view of a semiconductor package according to another exemplary embodiment;

FIG. 11 is a cross-sectional view of the semiconductor package of FIG. 10; and

FIGS. 12 to 14 are cross-sectional views of a method of manufacturing the semiconductor package shown in FIGS. 10 and 11.

### DETAILED DESCRIPTION OF EMBODIMENTS

Hereinafter, exemplary embodiments of the present invention will be described in detail with reference to the attached drawings. However, the present invention is not limited to the embodiments described below and may be embodied in various forms different therefrom. The following embodiments are provided to allow those skilled in the art to fully understand the scope of the present invention rather than to perfectly complete the present invention.

When it is described that one element is disposed on or connected to another element or layer, the element may be directly disposed on or directly connected to the other element and other elements or layers may be disposed therebetween. Differently, when it is described that one element is directly disposed on or directly connected to another element, there is no other element therebetween. To describe various elements, components, areas, layers, and/or parts, terms of first, second, third and the like may be used. However, the elements, components, areas, layers, and/or parts are not limited thereto.

Technical terms below are used to describe exemplary embodiments but not to limit the present invention. Alternatively, if not differently defined, all terms including technical and scientific terms have the same meanings that can be understood by a person of ordinary skill in the art. The terms as defined in general dictionaries may be understood to have meanings identical to contextual meanings thereof in descriptions of related art and the exemplary embodiments. If not definitively limited, they will not be understood as ideally or excessively external intuition.

The embodiments of the present invention will be described with reference to views of exemplary embodiments thereof. According thereto, variances from shapes of the views, for example, variances in manufacturing methods and/or allowable errors may be fully expected. Accordingly, the embodiments of the present invention will not be described as limited to specific shapes of areas illustrated in the drawings but will include deviations in the shapes, and areas illustrated in the drawings will be substantially schematic and shapes thereof will neither describe definite shapes of the areas and nor limit the scope of the present invention.

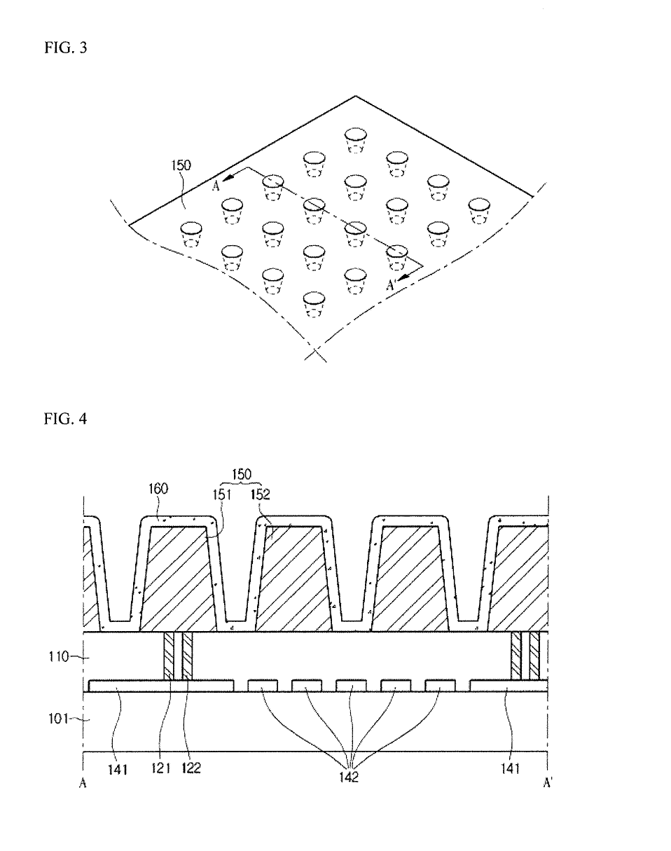

FIG. 3 is a view of a top surface of a semiconductor package according to an exemplary embodiment, and FIG. 4 is a cross-sectional view of the semiconductor package of FIG. 3. The semiconductor package may be used as a liquid crystal display (LCD) driver integrated circuit (IC) for controlling operations of an LCD panel, that is, a display panel. Differently, the semiconductor package may be used as a touch sensor driver IC for controlling operations of a touch panel.

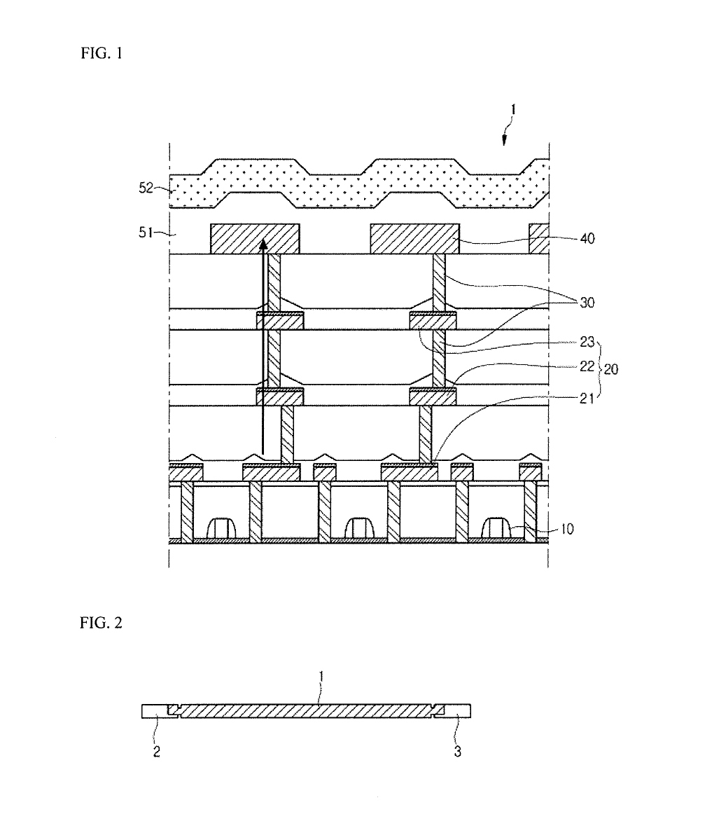

Referring to FIG. 4, although not shown in the drawing, a semiconductor substrate 101, as shown in FIG. 1, is formed with a plurality of transistors, a plurality of metal patterns electrically connected to the transistors, and via contacts.

The substrate 101 may be formed with a plurality of metal lines thereon. For example, the substrate 101 may be formed with a data metal line 142 transmitting or receiving signals to or from a display panel and a power metal line 141 for applying power to electrodes arranged as a matrix to display images on the display panel. That is, the data metal line 142 is electrically connected to the transistors to control operation of the display panel to allow data to be transmitted and received. The power metal line 141 provides the display panel with the power for displaying images.

The power metal line 141 is formed with metal contacts 121 and 122 providing a heat transfer path to release the heat. An insulating layer 110 is formed on the substrate 101, the power metal line 14 and the data metal line 142. The insulating layer 110 protects the power metal line 141 and the data metal line 142 from an electric short therebetween.

Also, the metal contacts 121 and 122 may be used to quickly transfer heat from the power metal line 141. A various number of the metal contacts 121 and 122 may be employed, and it should be understood that the number of contacts used in the illustration of FIG. 4 is not intended to limit the scope of the present invention.

A heat release layer 150 may be formed of metal material and electrically connected to the metal contacts 121 and 122 to release heat from the semiconductor package. This heat release layer 150 may be formed on the insulating layer 110. The heat release layer 150 may be formed not only over the power metal line 141 but also over the data metal line 142, thereby forming the entire insulating layer. Particularly, as shown in FIG. 3, the heat release layer 150 may have a plurality of holes and may include, as shown in FIG. 4, a first area 151 located over the power metal line 141 and a second area 152 located over the data metal line 142. Herein, the first area 151 and the second area 152 may be electrically connected to each other.

On the other hand, the semiconductor package may include a plurality of heat release layers 150 on the insulating layer 110. For example, when the semiconductor package includes power lines of 18 V and power lines of 9 V, a first heat release layer may be connected to the power lines of 18 V and a second heat release layer may be connected to the power lines of 9 V. Both of these heat release layers may be formed on the insulating layer 110.

Although the heat release layer 150 is formed as a single body on the insulating layer 110 as depicted in FIG. 4, the heat release layer 150 may alternatively or additionally be formed of a plurality of heat release patterns (not shown). For example, the plurality of heat release patterns may be formed on the insulating layer 110 connected to the power metal lines 141 through the metal contacts 121 and 122. The plurality of heat release patterns may have a lattice or stripe shape on the insulating layer 110.

On the heat release layer 150, a passivation layer 160 formed of a metallic material may be further formed for protecting the heat release layer 150. Since the passivation layer 160 is formed of an insulating material, it may have a relatively smaller thickness to effectively release heat.

FIGS. 5 to 7 are cross-sectional views illustrating a method of manufacturing the semiconductor package shown in FIG. 4. Referring to FIG. 5, the power metal lines 141 and the data metal lines 142 are formed on the semiconductor substrate 101 formed with transistors, metal wirings, and via contacts. After forming the power metal lines 141 and the data metal lines 142, the insulating layer 110 is formed on the substrate 101, the power metal lines 141 and the data metal lines 142. The power metal lines 141 and the data metal lines 142 are insulated from one another by the insulating layer 110.

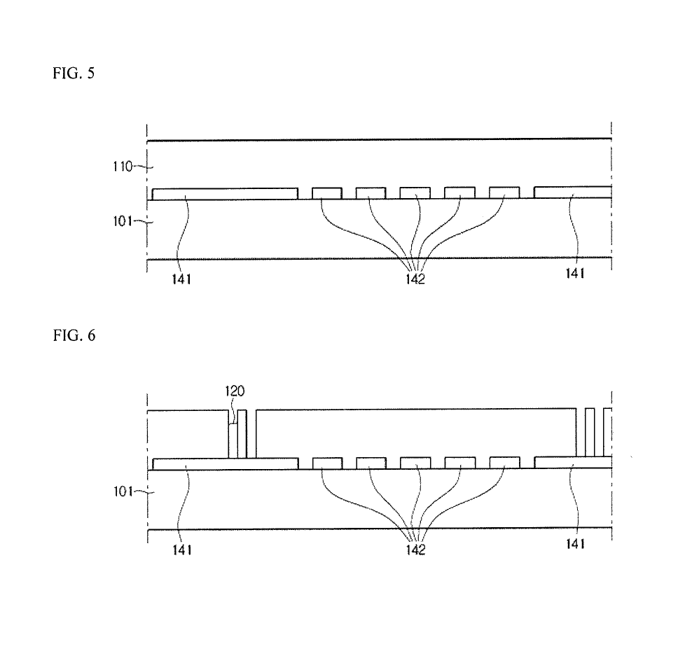

Referring to FIG. 6, the insulating layer 110 is partially etched to expose a part of the power metal lines 141. As an example, openings 120 partially exposing the power metal lines 141 are formed by performing an anisotropic dry etching process. The openings 120 may function as contact holes formed with the metal contacts 121 and 122. The number of the openings 120 may be variously changed and is not intended to limit the scope of the present invention.

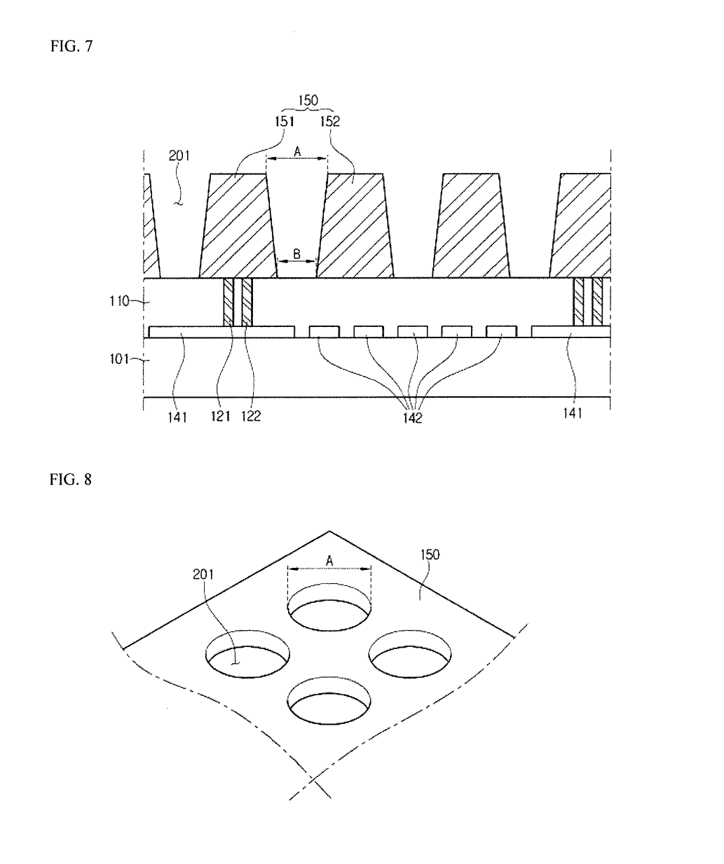

Referring to FIG. 7, the metal contacts 121 and 122 electrically connected to the power metal lines 141 are formed in the openings 120 and then the heat release layer 150 is formed on the insulating layer 110 and the metal contacts 121 and 122. As an example, the heat release layer 150 may be formed to have a thickness from about 2 to about 3 μm.

The metal contacts 121 and 122 and the heat release layer 150 may be formed using a chemical vapor deposition process. Particularly, a chemical vapor deposition process for forming the metal contacts 121 and 122 may be performed and then a planarization process such as chemical-mechanical polishing process may be performed.

After forming the heat release layer 150, the heat release layer 150 is partially removed through an etching process, thereby forming heat release holes 201 partially exposing the insulating layer 110.

On the other hand, a plurality of heat release layers 150 may be formed on the insulating layer 110, in which the heat release layers 150 may be electrically insulated from one another. That is, the heat release layers 150 may be connected to mutually different power metal lines 141, for example, to the power metal lines of 18 V and the power metal lines of 9 V, respectively.

According to the exemplary embodiment, a diameter of the heat release holes 201 may be reduced from a top surface to a bottom surface of the heat release layer 150. The heat release holes 201 may increase a surface area of the heat release layer 150, thereby improving a heat release effect through the heat release layer 150.

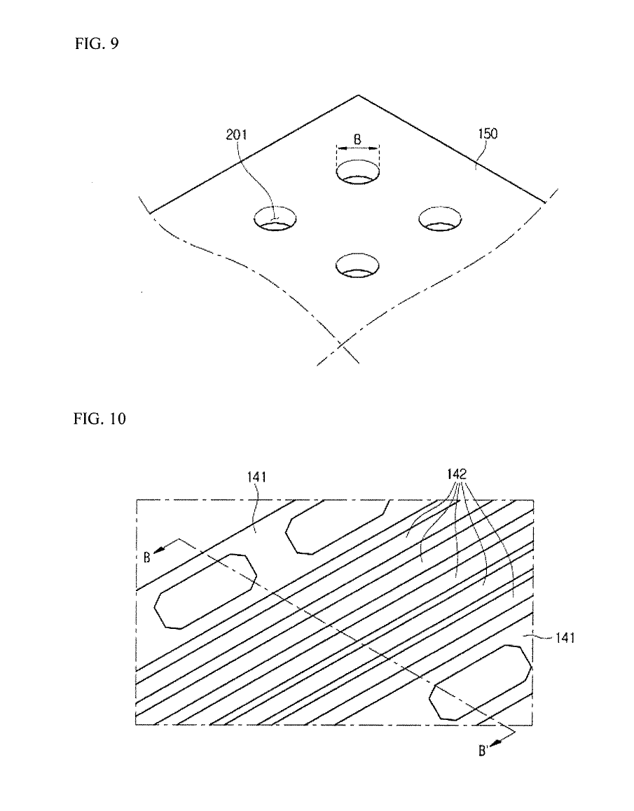

FIGS. 8 and 9 are perspective views of a top and a bottom of the heat release layer 150 shown in FIG. 7.

Referring to FIGS. 7 to 9, an upper portion of the heat release hole 201 formed on the top surface of the heat release layer 150 may have a diameter A and a lower portion of the heat release hole 201 may have a diameter B smaller than the diameter A.

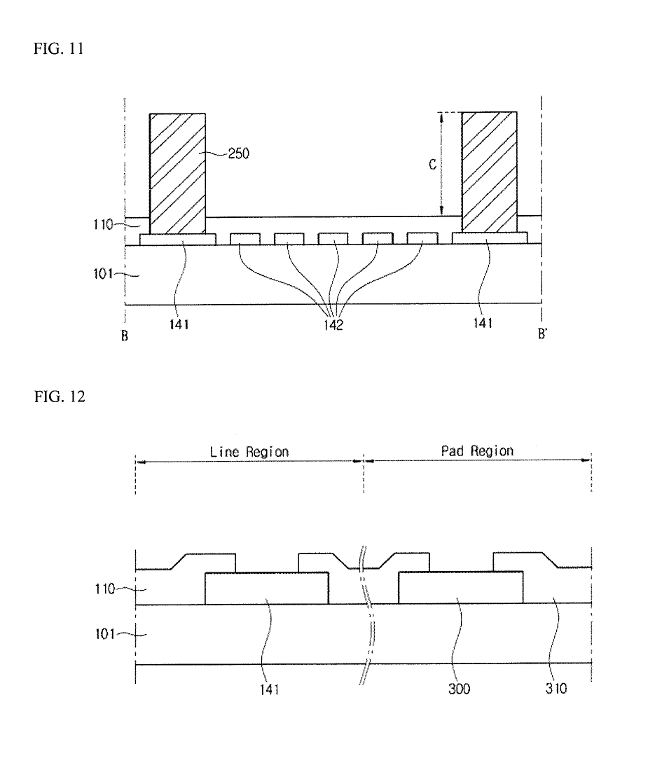

FIG. 10 is a top view of a semiconductor package according to another exemplary embodiment, and FIG. 11 is a cross-sectional view of the semiconductor package of FIG. 10.

Referring to FIGS. 10 and 11, the semiconductor package may be used as a driver IC of a display device and may include the data metal lines 142 for transmitting and receiving data signals with the transistors formed on a substrate and the power metal lines 141 applying power to the driver IC and a display panel.

In detail, the power metal lines 141 and the data metal lines 142 may be formed on the substrate 101 and the insulating layer 110 may be formed on the substrate 101, the power metal lines 141, and the data metal lines 142.

Referring to FIG. 10, the power metal lines 141 may be formed on both sides of a plurality of data metal lines 142 and heat release bumps may be formed on the power metal lines 141.

Referring to FIG. 11, the power metal lines 141 for applying power to the driver IC and the display panel and the data metal lines 142 for transmission and reception of data may be formed on the substrate 101 formed with a plurality of transistors, via contacts connected to the transistors, and metal patterns connected to the via contacts.

The insulating layer 110 may be formed on the substrate 101, the power metal lines 141, and the data metal lines 142 and then openings partially exposing the power metal lines 141 may be formed. The openings may be used to release heat from the power metal lines 141.

The heat release bumps 250 formed of metal material may be formed on top portions of the power metal lines 141 exposed by the openings to improve a heat release effect. The heat release bumps 250 may be formed to protrude from the insulating layer 110. A height C of the heat release bumps 250 protruding from the insulating layer 110 may be within a range of from about 10 to about 20 μm, and for example, may be about 15 μm.

The heat may be released from the power metal lines 141 through the openings. However, the heat release bumps 250 are formed on the power metal lines exposed by the openings, thereby more improving the heat release effect. Alternatively, the openings and the heat release bumps 250 may be formed together with a pad region of the semiconductor package.

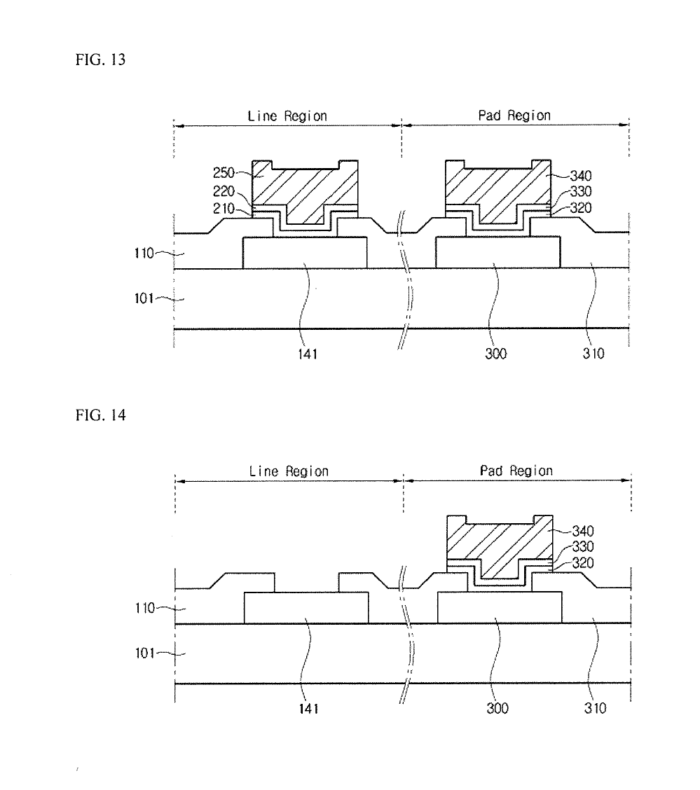

FIGS. 12 to 14 are cross-sectional views of a method of manufacturing the semiconductor package shown in FIGS. 10 and 11. Referring to FIGS. 12 and 13, the semiconductor package may have a line region and a pad region. The line region may be formed with the transistors, the power metal lines 141, and the data metal lines 142. The pad region may be formed with connection lines 300 for external connection. For example, the connection lines 300 for connection with the display panel may be formed in the pad region.

On the substrate 101, the power metal lines 141 and the connection lines 300 may be formed together. For example, a conductive material layer such as an aluminum layer is formed on the substrate 101 and is patterned using a photolithography process, thereby forming the power metal lines 141 and the connection lines 300 on the substrate 101.

The insulating layer 110 and an insulating layer 310 may be formed on the substrate 101, the power metal lines 141, and the connection lines 300, respectively, and then openings partially exposing the power metal lines 141 and the connection lines 300 may be formed through a photolithography process. As another example, the openings 120 (e.g., contact holes), as shown in FIG. 6, may be formed through the photolithography process with respect to the insulating layers 110 and 310.

After the openings are formed as described above, the heat release bumps 250 and pad bumps 340 may be formed in the openings.

For example, first and second metal layers are formed on the insulating layers 110 and 310 and the power metal lines 141 and the connection lines 300 partially exposed by the openings, and then are patterned, thereby forming first and second metal patterns 210, 220, 320, and 330.

Sequentially, the heat release bumps 250 and the pad bumps 340 may be formed on the first and second metal patterns 210, 220, 320, and 330 as shown in FIG. 13. The first and second metal patterns 210, 220, 320, and 330 may function as under bump metallurgy (UBM) layers or bonding layers and may be formed of one of chrome (Cr), nickel (Ni), titanium-tungsten (TiW), and copper (Cu). The heat release bumps 250 and the pad bumps 340 may be formed of one of gold (Au), lead (Pb), and tin (Sn) and may be formed using one of vapor deposition, electro-plating, and screen-printing.

As another example, while forming the first and second metal patterns 320 and 330 and the pad bumps 340, the metal contacts 121 and 122 and the heat release layer 150 as shown in FIG. 7 may be formed in the line region.

Alternately, as shown in FIG. 4, the heat release bumps 250 may not be formed on the power metal lines 141. In this case, heat may be released through the openings partially exposing the power metal lines 141. That is, the openings may function as heat release holes allowing heat to be released from the power metal lines 141.

According to some embodiments, the heat release layer 150 or the heat release bumps 250 connected to the power metal lines 141 of the semiconductor package are formed, thereby fully improving a heat release effect. Particularly, general heat sinks 2 and 3 may be removed, thereby reducing a size of the semiconductor package.

Although the semiconductor package has been described with reference to the specific embodiments, it is not limited thereto. Therefore, it will be readily understood by those skilled in the art that various modifications and changes can be made thereto without departing from the spirit and scope of the present invention defined by the appended claims.

What is claimed is:

1. A semiconductor package comprising:
a substrate formed with transistors;
power metal lines formed on the substrate;
data metal lines formed on the substrate to transmit and receive data to and from the transistors; and
an insulating layer formed on the substrate, the power metal lines, and the data metal lines,
wherein the insulating layer has openings partially exposing the power metal lines.

2. The semiconductor package of claim 1, further comprising:
metal contacts formed in the openings; and
a heat release layer formed on the metal contacts and the insulating layer, the heat release layer connected to the power metal lines through the metal contacts.

3. The semiconductor package of claim 2, wherein the heat release layer is formed of metal material and comprises a plurality of heat release patterns formed on the insulating layer.

4. The semiconductor package of claim 2, wherein the heat release layer comprises a first area located over the power metal lines and a second area located over the data metal lines.

5. The semiconductor package of claim 4, wherein the first area and the second area are electrically connected to each other.

6. The semiconductor package of claim 2, further comprising a passivation layer formed on the heat release layer.

7. The semiconductor package of claim 2, wherein the heat release layer has a plurality of heat release holes partially exposing the insulating layer.

8. The semiconductor package of claim 7, wherein the heat release holes have a diameter gradually reducing from a top surface to a bottom surface of the heat release layer.

9. The semiconductor package of claim 1, wherein the substrate comprises a pad region for external connection,
wherein connection lines and pad bumps connected to the connection lines are formed in the pad region, and
wherein the power metal lines and the connection lines are formed of the same material.

10. The semiconductor package of claim 9, wherein heat release bumps connected to the power metal lines are formed in the openings, respectively.

11. The semiconductor package of claim 10, wherein the heat release bumps are formed to protrude from the insulating layer.

12. The semiconductor package of claim 9, wherein the heat release bumps and the pad bumps are formed of the same material.

13. A semiconductor package for controlling a display panel, comprising:
a substrate formed with transistors;
power metal lines formed on the substrate;
data metal lines formed on the substrate to transmit and receive data to and from the transistors;
an insulating layer formed on the substrate, the power metal lines, and the data metal lines;
a heat release layer formed on the insulating layer; and
a plurality of metal contacts connecting the power metal lines with the heat release layer to each other through the insulating layer.

14. The semiconductor package of claim 13, wherein the heat release layer comprises a first area located over the power metal lines and a second area located over the data metal lines.

15. A semiconductor package comprising:
a substrate formed with transistors;
power metal lines formed on the substrate;
data metal lines formed on the substrate to transmit and receive data to and from the transistors; and
an insulating layer formed on the substrate, the power metal lines, and the data metal lines,
wherein the insulating layer has heat release holes partially exposing the power metal lines.

16. The semiconductor package of claim 15, further comprising heat release bumps formed on the power metal lines exposed by the heat release holes.
